(19) United States
(12) Patent Application Publication
(10) Pub. No.: US 2025/0146131 A1
(43) Pub. Date: May 8, 2025

(54) COMPOSITIONS AND METHODS USING SAME FOR CARBON DOPED SILICON CONTAINING FILMS

(71) Applicant: VERSUM MATERIALS US, LLC, TEMPE, AZ (US)

(72) Inventors: STEVEN GERARD MAYORGA, OCEANSIDE, CA (US); HARIPIN CHANDRA, SAN MARCOS, CA (US); XINJIAN LEI, VISTA, CA (US)

(21) Appl. No.: 18/865,652

(22) PCT Filed: May 10, 2023
(86) PCT No.: PCT/US2023/066844

§ 371 Date: Nov. 13, 2024

Related U.S. Application Data
(60) Provisional application No. 63/341,635, filed on May 13, 2022.

(51) Int. Cl. C23C 16/455; C23C 16/40; C23C 16/44; C23C 16/52; C23C 16/56

(52) U.S. Cl. CPC C23C 16/45553; C23C 16/401; C23C 16/4408; C23C 16/52; C23C 16/56

(57) ABSTRACT

A composition and method for using the composition in the fabrication of an electronic device are disclosed. Compounds, compositions and methods for depositing a low dielectric constant (<4.0) and high oxygen ash resistance silicon-containing film such as, without limitation, a carbon doped silicon oxide, are disclosed.

### CROSS-REFERENCE TO RELATED APPLICATIONS

This application claims the benefit of U.S. provisional patent application Ser. No. 63/341,635, filed on May 13, 2022.

### FIELD OF THE INVENTION

Described herein is a composition and method for the fabrication of an electronic device. More specifically, described herein are compounds, and compositions and methods comprising same, for the deposition of a low dielectric constant (<4.0) and high oxygen ash resistance silicon-containing film such as, without limitation, a carbon doped silicon oxide, a carbon doped silicon nitride, a carbon doped silicon oxynitride.

### BACKGROUND OF THE INVENTION

There is a need in the art to provide a composition and method using same for depositing high carbon content (e.g., a carbon content of about 10 atomic % or greater as measured by X-ray photoelectron spectroscopy (XPS)) doped silicon-containing films for certain applications within the electronics industry.

U.S. Pat. No. 8,575,033 describes methods for deposition of silicon carbide films on a substrate surface. The methods include the use of vapor phase carbosilane precursors and may employ plasma enhanced atomic layer deposition processes.

US Publ. No. 2013/022496 A teaches a method of forming a dielectric film having Si—C bonds on a semiconductor substrate by atomic layer deposition (ALD), includes: (i) adsorbing a precursor on a surface of a substrate; (ii) reacting the adsorbed precursor and a reactant gas on the surface; and (iii) repeating steps (i) and (ii) to form a dielectric film having at least Si—C bonds on the substrate.

PCT Publ. No. WO14134476 A1 describes methods for the deposition of films comprising SiCN and SiOCN. Certain methods involve exposing a substrate surface to a first and second precursor, the first precursor having a formula (X_{y}H_{3-y}Si)zCH_{4-z}, (X_{y}H_{3-y}Si)(CH₂)(SiXₚH₂₋ₚ)(CH₂)(SiX_{y}H_{3-y}), or (X_{y}H_{3-y}Si)(CH₂)ₙ(SiX_{y}H_{3-y}), wherein X is a halogen, y has a value of between 1 and 3, and z has a value of between 1 and 3, p has a value of between 0 and 2, and n has a value between 2 and 5, and the second precursor comprising a reducing amine. Certain methods also comprise exposure of the substrate surface to an oxygen source to provide a film comprising carbon doped silicon oxide.

Hirose, Y., Mizuno, K., Mizuno, N., Okubo, S., Okubo, S., Yanagida, K. and Yanagita, K. (2014)) “method of manufacturing semiconductor device, substrate processing apparatus, and recording medium” US Publ. No. 2014/287596 A describes a method of manufacturing a semiconductor device including forming a thin film containing silicon, oxygen and carbon on a substrate by performing a cycle a predetermined number of times, the cycle including: supplying a precursor gas containing silicon, carbon and a halogen element and having an Si—C bonding, and a first catalytic gas to the substrate; and supplying an oxidizing gas and a second catalytic gas to the substrate.

Hirose, Y., Mizuno, N., Yanagita, K. and Okubo, S. (2014)) “Method of manufacturing semiconductor device, substrate processing apparatus, and recording medium.” U.S. Pat. No. 9,343,290 B describes a method of manufacturing a semiconductor device includes forming an oxide film on a substrate by performing a cycle a predetermined number of times. The cycle includes supplying a precursor gas to the substrate; and supplying an ozone gas to the substrate. In the act of supplying the precursor gas, the precursor gas is supplied to the substrate in a state where a catalytic gas is not supplied to the substrate, and in the act of supplying the ozone gas, the ozone gas is supplied to the substrate in a state where an amine-based catalytic gas is supplied to the substrate.

U.S. Pat. No. 9,349,586 B discloses a thin film having a desirable etching resistance and a low dielectric constant.

US Publ. No. 2015/0044881 A describes a method to form a film containing carbon added at a high concentration is formed with high controllability. A method of manufacturing a semiconductor device includes forming a film containing silicon, carbon and a predetermined element on a substrate by performing a cycle a predetermined number of times. The predetermined element is one of nitrogen and oxygen. The cycle includes supplying a precursor gas containing at least two silicon atoms per one mol., carbon and a halogen element and having a Si—C bonding to the substrate, and supplying a modifying gas containing the predetermined element to the substrate.

The reference entitled “Highly Stable Ultrathin Carbosiloxane Films by Molecular Layer Deposition”, Han, Z. et al., Journal of Physical Chemistry C, 2013, 117, 19967 teaches growing carbosiloxane film using 1,2-bis[(dimethylamino)dimethylsilyl]ethane and ozone. Thermal stability shows film is stable up to 40° C. with little thickness loss at 60° C.

Liu et al, Jpn. J. Appl. Phys., 1999, Vol. 38, 3482-3486, teaches H₂ plasma use on polysilsesquioxane deposited with spin-on technology. The H₂ plasma provides stable dielectric constant and improves film thermal stability and O₂ ash (plasma) treatment.

Kim et al, Journal of the Korean Physical Society, 2002, Vol. 40, 94, teaches H₂ plasma treatment on PECVD carbon doped silicon oxide film improves leakage current density (4-5 orders of magnitude) while dielectric constant increases from 2.2 to 2.5. The carbon doped silicon oxide film after H₂ plasma has less damage to during oxygen ashing process.

Posseme et al, Solid State Phenomena, 2005, Vol. 103-104, 337, teaches different H₂/inert plasma treatment on carbon doped silicon oxide PECVD film. The k is not improving after H₂ plasma treatment suggesting no bulk modification.

There is a need to develop a liquid composition for chlorosilane precursors such as 1,1,3,3-tetrachloro-1,3-disilacyclobutane that is amenable to vapor phase delivery methods for ALD applications. The composition must meet certain critical requirements for successful commercialization including: the solvent must not react with the chlorosilane; the chlorosilane chemical must be highly soluble in the solvent; the chlorosilane must not precipitate or phase separate during transport when exposed to low temperature; the solvent must be manufacturable in high purity and dried to low water content; the formulated solution must have an acceptable viscosity; and the vapor pressure of the solvent must be similar to that of the chlorosilane chemical.

### BRIEF SUMMARY OF THE INVENTION

The composition described herein satisfies these criteria. The composition and method described herein overcome the problems of the prior art by providing a composition or formulation for depositing a conformal silicon-containing film forming having one or more of the following properties: i) a dielectric constant less than 4.0; ii) an etch rate (e.g., 0.22 Å/s in 1:99 dilute HF) of at most 0.5 times that of thermal silicon oxide (e.g., 0.45 Å/s in 1:99 dilute HF) as measured in dilute hydrofluoric acid and a carbon content of about 10 atomic weight percent (at. %) or greater as measured by X-ray photospectrometry (XPS); ii) oxygen ash resistance, i.e. decreased sensitivity of the film's dielectric constant and the film's wet etch rate in dilute HF (dHF) resulting from subjecting the film to an oxygen ashing process or exposure of the film to oxygen plasma; and (iv) chlorine impurity in the resulting films less than 2.0 at. %, preferably less than 1.0 at. %, most preferably less than 0.5 at. %. Oxygen ash resistance can be quantified by the film's damage thickness after an O₂ ashing process (e.g. damage thickness of <50 Å) measured by dHF dip. Oxygen ash resistance is also exemplary when the film dielectric constant after an O₂ ashing process remains lower than 4.0. The desirable properties that can be achieved by the instant invention are illustrated in greater detail in the Examples below.

In one particular embodiment, the composition described herein may be used in a method to deposit a carbon doped silicon oxide film using thermal atomic layer deposition (ALD).

In one aspect, disclosed is a composition for depositing silicon-containing films, the composition comprising: (a) 1,1,3,3-tetrachloro-1,3-disilacyclobutane; and (b) a solvent selected from the group consisting of mesitylene (b.p. 165° C.), 2-methyl-nonane (b.p. 167° C.), 1,2,4,5-tetramethylpiperazine (b.p. 166° C.), ethoxy-benzene (b.p. 171° C.), and 1-ethyl-4-methyl-benzene (b.p. 162° C.).

In one aspect, disclosed is a composition for depositing silicon-containing films, the composition comprising: (a) 1,1,3,3-tetrachloro-1,3-disilacyclobutane; and (b) mesitylene.

In another aspect, disclosed is a method for forming a carbon doped silicon oxide film having carbon content ranging from 15 at. % to 30 at. % via a thermal ALD process, the method comprising: a) placing one or more substrates comprising a surface feature into a reactor; b) heating the reactor to one or more temperatures ranging from ambient temperature to about 550° C. and optionally maintaining the reactor at a pressure of 100 torr or less; c) introducing a composition comprising 1,1,3,3-tetrachloro-1,3-disilacyclobutane and mesitylene into the reactor; d) purging with an inert gas; e) providing a nitrogen source into the reactor to react with the 1,1,3,3-tetrachloro-1,3-disilacyclobutane to form a carbon doped silicon nitride film; f) purging with inert gas to remove reaction by-products; g) repeating steps c to f to provide a desired thickness of the carbon doped silicon nitride film; h) treating the resulting carbon doped silicon nitride film with an oxygen source at one or more temperatures ranging from about ambient temperature to about 1000° C., or from about 100° C. to about 400° C. according to an embodiment, to convert the carbon doped silicon nitride film into a carbon doped silicon oxide film; exposing the carbon doped silicon oxide film to a plasma comprising hydrogen.

In yet another aspect, disclosed is a method for forming a carbon doped silicon oxide film having carbon content ranging from 15 at % to 30 at. % via a thermal ALD process, the method comprising: a) placing one or more substrates comprising a surface feature into a reactor; b) heating the reactor to one or more temperatures ranging from ambient temperature to about 150° C. and optionally maintaining the reactor at a pressure of 100 torr or less; c) introducing a composition comprising 1,1,3,3-tetrachloro-1,3-disilacyclobutane, mesitylene, and a catalyst into the reactor; d) purging the reactor with an inert gas; e) providing vapors of water into the reactor to react with the 1,1,3,3-tetrachloro-1,3-disilacyclobutane in the presence of the catalyst to form a carbon doped silicon oxide film; and f) purging the reactor with an inert gas to remove any reaction by-products, and repeating steps c) to f) to provide a desired thickness of the carbon doped silicon oxide film.

In still another aspect, disclosed is a stainless-steel container housing the inventive compositions.

The embodiments of the invention may be used alone or in various combinations with each other.

### BRIEF DESCRIPTION OF THE DRAWINGS

FIG. 1 illustrates an overlay of the vapor pressure curves of 1,1,3,3-tetrachloro-1,3-disilacyclo-butane and mesitylene;

FIG. 2 illustrates the concentration of a 20 wt. % solution of 1,1,3,3-tetrachloro-1,3-disilacyclobutane in mesitylene as a function of the percent of the material used in a container during a vapor draw delivery process; The square symbols indicated concentration profile when container was kept at 70° C.; The circle symbols indicated concentration profile when container was kept at 80° C.

FIG. 3 illustrates the concentration of common stainless-steel metals and assay are shown in this plot for a 20 wt. % solution of 1,1,3,3-tetrachloro-1,3-disilacyclobutane in mesitylene stored in stainless-steel commercial containers; and

FIG. 4 illustrates the Growth per Cycle (GPC) of film depositions with a composition comprising 1,1,3,3-tetrachloro-1,3-disilacyclobutane in mesitylene.

### DETAILED DESCRIPTION OF THE INVENTION

Described herein are compositions and methods to deposit a carbon doped (e.g., having a carbon content of about 10 at. % or greater as measured by XPS) silicon-containing film via a deposition process such as, without limitation, a thermal atomic layer deposition process. The film deposited using the composition and method described herein exhibits an extremely low etch rate such as an etch rate of at least 0.5 times less than thermal silicon oxide as measured in dilute hydrofluoric acid (e.g., about 0.22 Å/s or less or about 0.15 Å/s or less in dilute HF (0.5 wt. %, i.e. 1:99 dilute HF), or an etch rate (0.15 Å/s) of at most 0.1 times that of thermal silicon oxide, or an etch rate (0.02 Å/s) of at most 0.05 times that of thermal silicon oxide, or an etch rate of at most 0.01 times that of thermal silicon oxide while exhibiting variability in other tunable properties such as, without limitation, density, dielectric constant, refractive index, and elemental composition.

In certain embodiments, the silicon precursor described herein, and methods using same, impart one or more of the following features in the following manner. First, the as-deposited, reactive carbon-doped silicon nitride film is formed using the silicon precursor comprising two Si—C—Si linkages, and a nitrogen source. Without wishing to be bound by any theory or explanation, it is believed that some of the Si—C—Si linkage from the silicon precursor remains in the resulting as-deposited film and provides a high carbon content of at least 10 at. % or greater as measured by XPS (e.g., about 20 to about 30 at. %, about 10 to about 20 at. % and in some cases, about 10 to about 15 at. % carbon). Second, when exposing the as-deposited film to an oxygen source, such as water, either intermittently during the deposition process, as a post-deposition treatment, or a combination thereof, at least a portion or all of the nitrogen content in the film is converted to oxygen to provide a film selected from a carbon-doped silicon oxide or a carbon-doped silicon oxynitride film. The nitrogen in the as-deposited film is released as one or more nitrogen-containing by-products such as ammonia or an amine group.

In this or other embodiments, the final film is porous and has a density of about 1.7 grams/cubic centimeter (g/cc) or less and an etch rate of 0.20 Å/s or less in 0.5 wt. % dilute hydrogen fluoride.

In one aspect, the composition for depositing a silicon-containing film comprises: (a) 1,1,3,3-tetrachloro-1,3-disilacyclobutane; and; (b) mesitylene. In some embodiments, the composition can be delivered via direct liquid injection into a reactor chamber for silicon-containing film using conventional direct liquid injection equipment and methods. The concentration of 1,1,3,3-tetrachloro-1,3-disilacyclobutane in the solvent can range from 1 wt to 90 wt %, preferably 10 wt to 80 wt %, most preferably 15 to 60 wt % depending the selected solvent.

Mesitylene is an optimal solvent for the composition since it has a normal boiling point that is very similar to that of 1,1,3,3-tetrachloro-1,3-disilacyclobutane (165° C. and 167° C., respectively). The two components of this composition have similar boiling points and similar vapor pressure curves over the temperature range of interest. The similarity of volatility of the chlorosilane chemical and the solvent ensure that the composition of the vapor stream and that of the liquid formulated product remain constant as the formulated product is depleted during vapor phase delivery. This constancy of liquid and gas phase composition of the formulated product is important to ensure a reliable, robust deposition process. Mesitylene is also hydrophobic, and therefore, can be readily dried by practical known methods such as treatment with molecular sieves to produce a solvent with less than 10 ppm water or preferably less than 5 ppm water. Achieving such low water levels is of central importance as it will minimize the amount of acidic byproduct formation, such as HCl, when the chlorosilane, such as 1,1,3,3-tetrachloro-1,3-disilacyclobutane, is dissolved in the solvent. The elimination or reduction of trace HCl in the final blended product is critical for achieving a formulated product which is compatible with common container materials of construction such as stainless steel.

In another aspect, there is provided a method for depositing a film selected from a carbon-doped silicon oxide film and a carbon-doped silicon oxynitride film onto at least a surface of a substrate comprising: placing the substrate into a reactor; heating the reactor to one or more temperatures ranging from about 25° C. to about 550° C.; introducing into the reactor a formulation comprising (a) 1,1,3,3-tetrachloro-1,3-disilacyclobutane as a precursor; and (b) mesitylene; introducing into the reactor a nitrogen source to react with at least a portion of the precursor to form a carbon doped silicon nitride film; and treating the carbon doped silicon nitride film with an oxygen source at one or more temperatures ranging from about 25° C. to 1000° C. or from about 100° C. to 400° C. under conditions sufficient to convert the carbon doped silicon nitride film into a carbon doped silicon oxide film or carbon doped silicon oxynitride film. In certain embodiments, the carbon doped silicon oxide film or the carbon doped silicon oxynitride film has a carbon content of about 10 atomic weight percent (at. %) or greater as measured by XPS and an etch rate of at most 0.5 times that of thermal silicon oxide as measured in dilute hydrofluoric acid. If desired, the invention further comprises treating the carbon doped silicon containing film with hydrogen or hydrogen/inert plasma at 25° C. to 600° C.

In certain embodiments, the silicon-containing films comprise silicon and nitrogen. In these embodiments, the silicon-containing films deposited using the methods described herein are formed in the presence of a nitrogen-containing source. A nitrogen-containing source may be introduced into the reactor in the form of at least one nitrogen source and/or may be present incidentally in the other precursors used in the deposition process.

Suitable nitrogen-containing or nitrogen source gases may include, for example, ammonia, ammonia plasma, hydrazine, monoalkylhydrazine, symmetrical or unsymmetrical dialkylhydrazine, organoamines such as methylamine, ethylamine, ethylenediamine, ethanolamine, piperazine, N,N′-dimethylethylenediamine, imidazolidine, cyclotrimethylenetriamine, and combination thereof.

In another aspect, there is provided a method for forming a carbon-doped silicon oxide film having carbon content ranging from 15 at. % to 30 at. % via a thermal ALD process, the method comprising: a) placing one or more substrates comprising a surface feature into a reactor; b) heating to reactor to one or more temperatures ranging from ambient temperature to about 550° C. and optionally maintaining the reactor at a pressure of 100 torr or less; c) introducing a composition comprising 1,1,3,3-tetrachloro-1,3-disilacyclobutane and mesitylene into the reactor; d) purging with an inert gas; e) providing a nitrogen source into the reactor to react with the 1,1,3,3-tetrachloro-1,3-disilacyclobutane to form a carbon doped silicon nitride film; f) purging with an inert gas to remove reaction by-products; g) repeating steps c to f to provide a desired thickness of the carbon doped silicon nitride film; h) treating the resulting carbon doped silicon nitride film with an oxygen source at one or more temperatures ranging from about ambient temperature to about 1000° C. or from about 100° C. to about 400° C. to convert the carbon doped silicon nitride film into a carbon doped silicon oxide film; and providing post-deposition exposing the carbon doped silicon oxide film to a plasma comprising hydrogen.

In another embodiment, provided is a method for forming a carbon-doped silicon oxide film having carbon content ranging from 15 at % to 30 at. % via a thermal ALD process, the method comprising the method comprising: a) placing one or more substrates comprising a surface feature into a reactor; b) heating the reactor to one or more temperatures ranging from ambient temperature to about 150° C. and optionally maintaining the reactor at a pressure of 100 torr or less; c) introducing a composition comprising 1,1,3,3-tetrachloro-1,3-disilacyclobutane, mesitylene, and a catalyst into the reactor; d) purge with an inert gas; e) providing vapors of water into the reactor to react with the 1,1,3,3-tetrachloro-1,3-disilacyclobutane in the presence of the catalyst to form a carbon doped silicon oxide as-deposited film; and f) purging with an inert gas to remove reaction by-products, wherein steps c) to f) are repeated to provide a desired thickness of the carbon doped silicon oxide film.

In one embodiment of the method described herein, the carbon doped silicon oxide film having carbon content ranging from 5 at. % to 20 at. % is deposited using a thermal ALD process and a plasma comprising hydrogen to improve film properties. In this embodiment, the method comprises:
a. placing one or more substrates comprising a surface feature into a reactor
b. heating to reactor to one or more temperatures ranging from ambient temperature to about 550° C. and optionally maintaining the reactor at a pressure of 100 torr or less;
c. introducing a composition comprising 1,1,3,3-tetrachloro-1,3-disilacyclobutane as a silicon precursor and mesitylene into the reactor;
d. purge with an inert gas thereby removing unreacted silicon precursor and forming a composition comprising the purge gas and the silicon precursor;
e. providing a nitrogen source into the reactor to react with the silicon precursor to form a carbon-doped silicon nitride film;
f. purge with inert gas to remove reaction by-products;
g. steps c to f are repeated to provide a desired thickness of the carbon doped silicon nitride film;
h. providing post-deposition treating the carbon doped silicon nitride film with an oxygen source at one or more temperatures ranging from about ambient temperature to 1000° C. or from about 100° to 400° C. to convert the carbon doped silicon nitride film into a carbon doped silicon oxide film either in situ or in another chamber; and
i. providing post-deposition exposing the carbon doped silicon oxide film to a plasma comprising hydrogen to improve film properties to improve at least one of the films' properties;
j. optionally post-deposition treating the carbon doped silicon oxide film with a spike anneal at temperatures from 400 to 1000 C or a UV light source. In this or other embodiments, the UV exposure step can be carried out either during film deposition, or once deposition has been completed.

In one embodiment, the substrate includes at least one feature wherein the feature comprises a pattern trench with aspect ratio of 1:9, opening of 180 nm.

In another embodiment, disclosed is a method for depositing a carbon doped silicon oxide film having carbon content ranging from 5 at. % to 20 at. % is deposited using a thermal ALD process and a plasma comprising hydrogen to improve film properties. In this embodiment, the method comprising the steps of:
a. placing one or more substrates comprising a surface feature into a reactor;
b. heating to reactor to one or more temperatures ranging from ambient temperature to about 550° C. and optionally maintaining the reactor at a pressure of 100 torr or less;
c. introducing a composition comprising 1,1,3,3-tetrachloro-1,3-disilacyclobutane and a solvent selected from the group consisting of mesitylene, 2-methyl-nonane, 1,2,4,5-tetramethylpiperazine, ethoxy-benzene, and 1-ethyl-4-methyl-benzene into the reactor;
d. purge with an inert gas thereby removing unreacted silicon precursor and forming a composition comprising the purge gas and silicon precursor;
e. providing a nitrogen source into the reactor to react with the surface to form a carbon-doped silicon film;
f. purge with inert gas to remove reaction by-products;
g. steps c to f are repeated to provide a desired thickness of the carbon-doped silicon nitride film;
h. providing post-deposition treating the carbon doped silicon nitride film with an oxygen source at one or more temperatures ranging from about ambient temperature to 1000° C. or from about 100° to 400° C. to convert the carbon-doped silicon nitride film into a carbon-doped silicon oxide film either in situ or in another chamber; and
i. providing post-deposition exposing the carbon doped silicon oxide film to a plasma comprising hydrogen to improve at least one of the films' properties; and
j. optionally post-deposition treating the carbon doped silicon oxide film with a spike anneal at temperatures from 400 to 1000° C. or a UV light source.

In this or other embodiments, the UV exposure step can be carried out either during film deposition, or once deposition has been completed.

In an embodiment of the method described herein, the carbon doped silicon oxide film having carbon content ranging from 15 at. % to 30 at. % is deposited using a thermal ALD process and a plasma comprising hydrogen to improve film properties. In this embodiment, the method comprises:
a. placing one or more substrates comprising a surface feature into a reactor (e.g., into a conventional ALD reactor);
b. heating to reactor to one or more temperatures ranging from ambient temperature to about 550° C. and optionally maintaining the reactor at a pressure of 100 torr or less;
c. introducing a composition comprising 1,1,3,3-tetrachloro-1,3-disilacyclobutane and mesitylene into the reactor;
d. purge with an inert gas;
e. providing a nitrogen source into the reactor to react with the 1,1,3,3-tetrachloro-1,3-disilacyclobutane to form a carbon-doped silicon nitride film;
f. purge with an inert gas to remove reaction by-products;
g. steps c to f are repeated to provide a desired thickness of the carbon doped silicon nitride film;
h. providing post-deposition treating the carbon doped silicon nitride film with an oxygen source at one or more temperatures ranging from about ambient temperature to 1000° C. or from about 100° to 400° C. to convert the carbon doped silicon nitride film into a carbon doped silicon oxide film either in situ or in another chamber;
i. providing post-deposition exposing the carbon doped silicon oxide film to a plasma comprising hydrogen to improve at least one of the films' physical properties; and
j. optionally post-deposition treating the carbon doped silicon oxide film with a thermal anneal at temperatures from 400 to 1000° C. or a UV light source.

In this or other embodiments, the UV exposure step can be carried out either during film deposition, or once deposition has been completed.

In yet another further embodiment of the method described herein, the silicon containing film is deposited using a thermal ALD process with a catalyst comprising an ammonia or organic amine. In this embodiment, the method comprises:
a. placing one or more substrates comprising a surface feature into a reactor;
b. heating the reactor to one or more temperatures ranging from ambient temperature to about 150° C. and optionally maintaining the reactor at a pressure of 100 torr or less;
c. introducing a composition comprising 1,1,3,3-tetrachloro-1,3-disilacyclobutane, mesitylene, and a catalyst into the reactor;
d. purge with an inert gas;
e. providing vapors of water into the reactor to react with the 1,1,3,3-tetrachloro-1,3-disilacyclobutane in the presence of the catalyst to form a carbon doped silicon oxide as-deposited film;
f. purge with an inert gas to remove reaction by-products;
g. steps c to f are repeated to provide a desired thickness of the carbon doped silicon oxide film;
h. providing post-deposition exposing the film to a plasma comprising hydrogen to improve at least one of the films' properties; and
i. optionally post-deposition treating the carbon doped silicon oxide film with a spike anneal at temperatures from 400 to 1000 C or a UV light source. In this or other embodiments, the UV exposure step can be carried out either during film deposition, or once deposition has been completed.

In this or other embodiments, the catalyst is selected from a Lewis base such as pyridine, piperazine, ammonia, triethylamine or other organic amines. The amount of Lewis base vapors is at least one equivalent to the amount of the silicon precursor vapors during step c.

In certain embodiments, the resulting carbon doped silicon oxide film is exposed to organoaminosilanes or chlorosilanes having Si-Me or Si—H or both to form a hydrophobic thin layer before exposing to hydrogen plasma treatment. Suitable organoaminosilanes include, but not limited to, diethylaminotrimethylsilane, dimethylaminotrimethylsilane, ethylmethylaminotrimethylsilane, t-butylaminotrimethylsilane, iso-propylaminotrimethylsilane, di-isopropylaminotrimethylsilane, pyrrolidinotrimethylsilane, diethylaminodimethylsilane, dimethylaminodimethylsilane, ethylmethylaminodimethylsilane, t-butylaminodimethylsilane, iso-propylaminodimethylsilane, di-isopropylaminodimethylsilane, pyrrolidinodimethylsilane, bis(diethylamino)dimethylsilane, bis(dimethylamino)dimethylsilane, bis(ethylmethylamino)dimethylsilane, bis(di-isopropyllamino)dimethylsilane, bis(iso-propylamino)dimethylsilane, bis(tert-butylamino)dimethylsilane, dipyrrolidinodimethylsilane, bis(diethylamino)diethylsilane, bis(diethylamino)methylvinylsilane, bis(dimethylamino)methylvinylsilane bis(ethylmethylamino)methylvinylsilane, bis(di-isopropyllamino)methylvinylsilane, bis(iso-propylamino)methylvinylsilane, bis(tert-butylamino)methylvinylsilane, dipyrrolidinomethylvinylsilane, 2,6-dimethylpiperidinomethylsilane, 2,6-dimethylpiperidinodimethylsilane, 2,6-dimethylpiperidinotrimethylsilane, tris(dimethylamino)phenylsilane, tris(dimethylamino)methylsilane, di-iso-propylaminosilane, di-sec-butylaminosilane, chlorodimethylsilane, chlorotrimethylsilane, dichloromethylsilane, and dichlorodimethylsilane.

In another embodiments, the resulting carbon doped silicon oxide film is exposed to alkoxysilanes or cyclic alkoxysilanes having Si-Me or Si—H or both to form a hydrophobic thin layer before exposing to hydrogen plasma treatment. Suitable alkoxysilanes or cyclic alkoxysilanes include, but not limited to, diethoxymethylsilane, dimethoxymethylsilane, diethoxydmethylsilane, dimethoxydmethylsilane, 2,4,6,8-Tetramethylcyclotetrasiloxane, or octamethylcyclotetrasiloxane. Without wishing to be bound by any theory or explanation, it is believed that the thin layer formed by the organoaminosilanes or alkoxysilanes or cyclic alkoxysilanes may convert into dense carbon doped silicon oxide during plasma ashing process, further boosting the ashing resistance.

In another embodiment, a vessel for depositing a silicon-containing film comprising one or more silicon precursor compounds described herein. In one particular embodiment, the vessel comprises at least one pressurizable vessel (preferably of stainless steel having a design such as disclosed in U.S. Pat. Nos. U.S. Pat. Nos. 7,334,595; 6,077,356; 5,069,244; and 5,465,766 the disclosure of which is hereby incorporated by reference. The container can comprise either glass (borosilicate or quartz glass) or type 316, 316L, 304 or 304L stainless steel alloys (UNS designation S31600, S31603, S30400 S30403) fitted with the proper valves and fittings to allow the delivery of one or more precursors to the reactor for a CVD or an ALD process. In this or other embodiments, the silicon precursor is provided in a pressurizable vessel comprised of stainless steel and the purity of the precursor is 98% by weight or greater or 99.5% or greater which is suitable for the semiconductor applications. The silicon precursor compounds are preferably substantially free of metal ions such as, Al³⁺ ions, Fe²⁺, Fe³⁺, Ni²⁺, Cr³⁺. As used herein, the term “substantially free” as it relates to Al³⁺ ions, Fe²⁺, Fe³⁺, Ni²⁺, Cr³⁺ means less than about 5 ppm (by weight), preferably less than about 3 ppm, and more preferably less than about 1 ppm, and most preferably about 0.1 ppm. In certain embodiments, such vessels can also have means for mixing the precursors with one or more additional precursor if desired. In these or other embodiments, the contents of the vessel(s) can be premixed with an additional precursor. Alternatively, the silicon precursor is and/or other precursor can be maintained in separate vessels or in a single vessel having separation means for maintaining the silicon precursor is and other precursor separate during storage.

The silicon-containing film is deposited upon at least a surface of a substrate such as a semiconductor substrate. In the method described herein, the substrate may be comprised of and/or coated with a variety of materials well known in the art including films of silicon such as crystalline silicon or amorphous silicon, silicon oxide, silicon nitride, amorphous carbon, silicon oxycarbide, silicon oxynitride, silicon carbide, germanium, germanium doped silicon, boron doped silicon, metal such as copper, tungsten, aluminum, cobalt, nickel, tantalum), metal nitride such as titanium nitride, tantalum nitride, metal oxide, group Ill/V metals or metalloids such as GaAs, InP, GaP and GaN, and a combination thereof. These coatings may completely coat the semi-conductor substrate, may be in multiple layers of various materials and may be partially etched to expose underlying layers of material. The surface may also have on it a photoresist material that has been exposed with a pattern and developed to partially coat the substrate. In certain embodiments, the semiconductor substrate comprising at least one surface feature selected from the group consisting of pores, vias, trenches, and combinations thereof. The potential application of the silicon-containing films include but not limited to low k spacer for FinFET or nanosheet, sacrificial hard mask for self aligned patterning process (such as SADP, SAQP, or SAOP).

The deposition method used to form the silicon-containing films or coatings are deposition processes. Examples of suitable deposition processes for the method disclosed herein include, but are not limited to, a chemical vapor deposition or an atomic layer deposition process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. As used herein, the term “thermal atomic layer deposition process” refers to atomic layer deposition process at substrate temperatures ranging from room temperature to 600° C. without in situ or remote plasma. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator.

In one embodiment, the silicon-containing film is deposited using an ALD process. In another embodiment, the silicon-containing film is deposited using a CCVD process. In a further embodiment, the silicon-containing film is deposited using a thermal ALD process. The term “reactor” as used herein, includes without limitation, reaction chamber or deposition chamber.

In certain embodiments, the method disclosed herein avoids pre-reaction of precursor(s) by using ALD or CCVD methods that separate the precursor(s) prior to and/or during the introduction to the reactor. In this connection, deposition techniques such as ALD or CCVD processes are used to deposit the silicon-containing film. In one embodiment, the film is deposited via an ALD process in a typical single wafer ALD reactor, semi-batch ALD reactor, or batch furnace ALD reactor by exposing the substrate surface alternatively to the one or more the silicon-containing precursor, oxygen source, nitrogen-containing source, or other precursor or reagent. Film growth proceeds by self-limiting control of surface reaction, the pulse length of each precursor or reagent, and the deposition temperature. However, once the surface of the substrate is saturated, the film growth ceases. In another embodiment, each reactant including the silicon precursor and reactive gas is exposed to a substrate by moving or rotating the substrate to different sections of the reactor and each section is separated by inert gas curtain, i.e. spatial ALD reactor or roll to roll ALD reactor.

Depending upon the deposition method, in certain embodiments, the silicon precursors described herein and optionally other silicon-containing precursors may be introduced into the reactor at a predetermined molar volume, or from about 0.1 to about 1000 micromoles. In this or other embodiments, the precursor may be introduced into the reactor for a predetermined time period. In certain embodiments, the time period ranges from about 0.001 to about 500 seconds.

In certain embodiments, the silicon-containing films deposited using the methods described herein are formed in the presence of a catalyst in combination with an oxygen source, reagent or precursor comprising oxygen, i.e., water vapors. An oxygen source may be introduced into the reactor in the form of at least one oxygen source and/or may be present incidentally in the other precursors used in the deposition process. Suitable oxygen source gases may include, for example, water (H₂O) (e.g., deionized water, purified water, distilled water, water vapor, water vapor plasma, oxygenated water, air, a composition comprising water and other organic liquid), oxygen (O₂), oxygen plasma, ozone (O₃), nitric oxide (NO), nitrogen dioxide (NO₂), carbon monoxide (CO), a plasma comprising water, a plasma comprising water and argon, hydrogen peroxide, a composition comprising hydrogen, a composition comprising hydrogen and oxygen, carbon dioxide (CO₂), air, and combinations thereof. In certain embodiments, the oxygen source comprises an oxygen source gas that is introduced into the reactor at a flow rate ranging from about 1 to about 10000 square cubic centimeters (sccm) or from about 1 to about 1000 sccm. The oxygen source can be introduced for a time that ranges from about 0.1 to about 100 seconds. The catalyst is selected from a Lewis base such as pyridine, piperazine, trimethylamine, tert-butylamine, diethylamine, trimethylamine, ethylenediamine, ammonia, or other organic amines.

In embodiments wherein the film is deposited by an ALD or a cyclic CVD process, the precursor pulse can have a pulse duration that is greater than 0.01 seconds, and the oxygen source can have a pulse duration that is less than 0.01 seconds, while the water pulse duration can have a pulse duration that is less than 0.01 seconds.

In certain embodiments, the oxygen source is continuously flowing into the reactor while precursor pulse and plasma are introduced in sequence. The precursor pulse can have a pulse duration greater than 0.01 seconds while the plasma duration can range between 0.01 seconds to 100 seconds.

In certain embodiments, the silicon-containing films comprise silicon and nitrogen. In these embodiments, the silicon-containing films deposited using the methods described herein are formed in the presence of nitrogen-containing source. A nitrogen-containing source may be introduced into the reactor in the form of at least one nitrogen source and/or may be present incidentally in the other precursors used in the deposition process.

Suitable nitrogen-containing or nitrogen source gases may include, for example, ammonia, hydrazine, monoalkylhydrazine, symmetrical or unsymmetrical dialkylhydrazine, organoamines such as methylamine, ethylamine, ethylenediamine, ethanolamine, piperazine, N,N′-dimethylethylenediamine, imidazolidine, cyclotrimethylenetriamine, and combination thereof.

In certain embodiments, the nitrogen source is introduced into the reactor at a flow rate ranging from about 1 to about 10000 square cubic centimeters (sccm) or from about 1 to about 1000 sccm. The nitrogen-containing source can be introduced for a time that ranges from about 0.1 to about 100 seconds. In embodiments wherein the film is deposited by an ALD or a cyclic CVD process using both a nitrogen and oxygen source, the precursor pulse can have a pulse duration that is greater than 0.01 seconds, and the nitrogen source can have a pulse duration that is less than 0.01 seconds, while the water pulse duration can have a pulse duration that is less than 0.01 seconds. In yet another embodiment, the purge duration between the pulses that can be as low as 0 seconds or is continuously pulsed without a purge in-between.

The deposition methods disclosed herein may involve one or more purge gases.

The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, hydrogen (H₂), and combinations thereof. In certain embodiments, a purge gas such as Ar is supplied into the reactor at a flow rate ranging from about 10 to about 10000 sccm for about 0.1 to 1000 seconds, thereby purging the unreacted material and any byproduct that may remain in the reactor.

The respective step of supplying the precursors, oxygen source, the nitrogen-containing source, and/or other precursors, source gases, and/or reagents may be performed by changing the time for supplying them to change the stoichiometric composition of the resulting film.

Energy is applied to the at least one of the precursor, nitrogen-containing source, reducing agent, other precursors or combination thereof to induce reaction and to form the film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof.

In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

Throughout the description, the term “ALD or ALD-like” refers to a process including, but not limited to, the following processes: a) each reactant including silicon precursor and reactive gas is introduced sequentially into a reactor such as a single wafer ALD reactor, semi-batch ALD reactor, or batch furnace ALD reactor; b) each reactant including silicon precursor and reactive gas is exposed to a substrate by moving or rotating the substrate to different sections of the reactor and each section is separated by inert gas curtain, i.e., spatial ALD reactor or roll to roll ALD reactor.

The silicon precursors and/or other silicon-containing precursors may be delivered to the reaction chamber, such as a CVD or ALD reactor, in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

In a still further embodiment of the method described herein, the film or the as-deposited film is subjected to a treatment step. The treatment step can be conducted during at least a portion of the deposition step, after the deposition step, and combinations thereof. Exemplary treatment steps include, without limitation, treatment via high temperature thermal annealing; plasma treatment; ultraviolet (UV) light treatment; laser; electron beam treatment and combinations thereof to affect one or more properties of the film. The films deposited with the silicon precursors having one or two Si—C—Si linkages described herein, when compared to films deposited with previously disclosed silicon precursors under the same conditions, have improved properties such as, without limitation, a wet etch rate that is lower than the wet etch rate of the film before the treatment step or a density that is higher than the density prior to the treatment step. In one particular embodiment, during the deposition process, as-deposited films are intermittently treated. These intermittent or mid-deposition treatments can be performed, for example, after each ALD cycle, after a certain number of ALD, such as, without limitation, one (1) ALD cycle, two (2) ALD cycles, five (5) ALD cycles, or after every ten (10) or more ALD cycles.

In an embodiment wherein the film is treated with a high temperature annealing step, the annealing temperature is at least 100° C. or greater than the deposition temperature. In this or other embodiments, the annealing temperature ranges from about 400° C. to about 1000° C. In this or other embodiments, the annealing treatment can be conducted in a vacuum (<760 Torr), inert environment or in oxygen containing environment (such as H₂O, N₂O, NO₂ or O₂)

In an embodiment wherein the film is treated to UV treatment, film is exposed to broad band UV or, alternatively, an UV source having a wavelength ranging from about 150 nanometers (nm) to about 400 nm. In one particular embodiment, the as-deposited film is exposed to UV in a different chamber than the deposition chamber after a desired film thickness is reached.

In an embodiment where in the film is treated with a plasma, passivation layer such as SiO₂ or carbon doped SiO₂ is deposited to prevent chlorine and nitrogen contamination from penetrating film in the subsequent plasma treatment. The passivation layer can be deposited using atomic layer deposition or cyclic chemical vapor deposition.

In an embodiment wherein the film is treated with a plasma, the plasma source is selected from the group consisting of hydrogen plasma, plasma comprising hydrogen and helium, plasma comprising hydrogen and argon. Hydrogen plasma lowers film dielectric constant and boost the damage resistance to following plasma ashing process while still keeping the carbon content in the bulk almost unchanged.

Throughout the description, the term “ALD or ALD-like” refers to a process including, but not limited to, the following processes: a) each reactant including silicon precursor and reactive gas is introduced sequentially into a reactor such as a single wafer ALD reactor, semi-batch ALD reactor, or batch furnace ALD reactor; b) each reactant including silicon precursor and reactive gas is exposed to a substrate by moving or rotating the substrate to different sections of the reactor and each section is separated by inert gas curtain, i.e., spatial ALD reactor or roll to roll ALD reactor.

Throughout the description, the term “ashing” refers to a process to remove the photoresist or carbon hard mask in semiconductor manufacturing process using a plasma comprising an oxygen source such as O₂/inert gas plasma, O₂ plasma, CO₂ plasma, CO plasma, H₂/O₂ plasma or combination thereof.

Throughout the description, the term “damage resistance” refers to film properties after oxygen ashing process. Good or high damage resistance is defined as the following film properties after oxygen ashing: film dielectric constant lower than 4.5; carbon content in the bulk (at more than 50 Å deep into film) is within 5 at. % as before ashing; Less than 50 Å of the film is damaged, observed by differences in dilute HF etch rate between films near surface (less than 50 Å deep) and bulk (more than 50 Å deep).

Throughout the description, the term “alkyl hydrocarbon” refers a linear or branched C₁ to C₂₀ hydrocarbon, cyclic C₆ to C₂₀ hydrocarbon. Exemplary hydrocarbon includes, but not limited to, heptane, octane, nonane, decane, dodecane, cyclooctane, cyclononane, and cyclodecane.

Throughout the description, the term “aromatic hydrocarbon” refers a C₆ to C₂₀ aromatic hydrocarbon. Exemplary aromatic hydrocarbon n includes, but not limited to, toluene, and mesitylene.

Throughout the description, the term “catalyst” refers a Lewis base in vapor phase which can catalyze surface reaction between hydroxyl group and Si—CI bond during thermal ALD process. Exemplary catalysts include, but not limited to, at least one of a cyclic amine-based gas such as aminopyridine, picoline, lutidine, piperazine, piperidine, pyridine or an organic amine-based gas methylamine, dimethylamine, trimethylamine, ethylamine, diethylamine, triethylamine, propylamine, iso-propylamine, di-propylamine, di-iso-propylamine, and tert-butylamine.

Throughout the description, the term “organic amines” refers a primary amine, secondary amine, tertiary amine having C₁ to C₂₀ hydrocarbon, cyclic C₆ to C₂₀ hydrocarbon. Exemplary organic amines include, but not limited to, methylamine, dimethylamine, trimethylamine, ethylamine, diethylamine, triethylamine, propylamine, iso-propylamine, di-propylamine, di-iso-propylamine, and tert-butylamine.

Throughout the description, the term “siloxanes” refer a linear, branched, or cyclic liquid compound having at least one Si—O—Si linkages and C₄ to C₂₀ carbon atoms.

Exemplary siloxanes includes, but not limited to, tetramethyldisiloxane, hexamethyldisiloxane (HMDSO), 1,1,1,3,3,5,5,5-octamethyltrisiloxane, and octamethylcyclotetrasiloxane (OMCTS).

Throughout the description, when using the term “an etch rate of at most x times that of thermal silicon oxide,” the value x is calculated by the etch rate of the subject silicon-containing film in 1:99 dilute HF divided by the etch rate of thermal silicon oxide in 1:99 dilute HF (e.g. 0.45 Å/s), with both etch rates being measured under the same conditions.

Throughout the description, the term “step coverage” as used herein is defined as a percentage of two thicknesses of the deposited film in a structured or featured substrate having either vias or trenches or both, with bottom step coverage being the ratio (in %): thickness at the bottom of the feature is divided by thickness at the top of the feature, and middle step coverage being the ratio (in %): thickness on a sidewall of the feature is divided by thickness at the top of the feature. Films deposited using the method described herein exhibit a step coverage of about 80% or greater, or about 90% or greater which indicates that the films are conformal.

The following examples illustrate certain aspects of the instant invention and do not limit the scope of the appended claims.

### EXAMPLES

### Example 1. A formulated product consisting of 20 wt. % 1,1,3,3-tetrachloro-1,3-disilacyclobutane in mesitylene

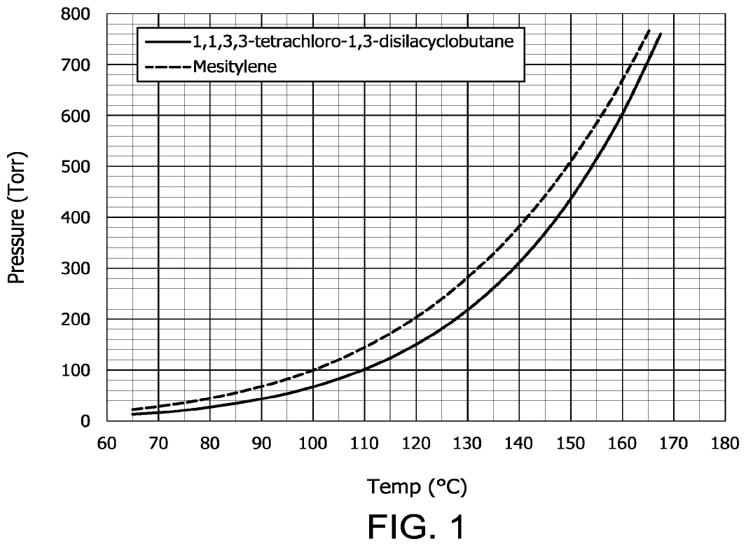

Formulation was prepared by dissolving 20% wt. 1,1,3,3-tetrachloro-1,3-disilacyclobutane in mesitylene. FIG. 1 shows an overlay of the vapor pressure curves of 1,1,3,3-tetrachloro-1,3-disilacyclo-butane with mesitylene showing their similarity over the temperature range of interest.

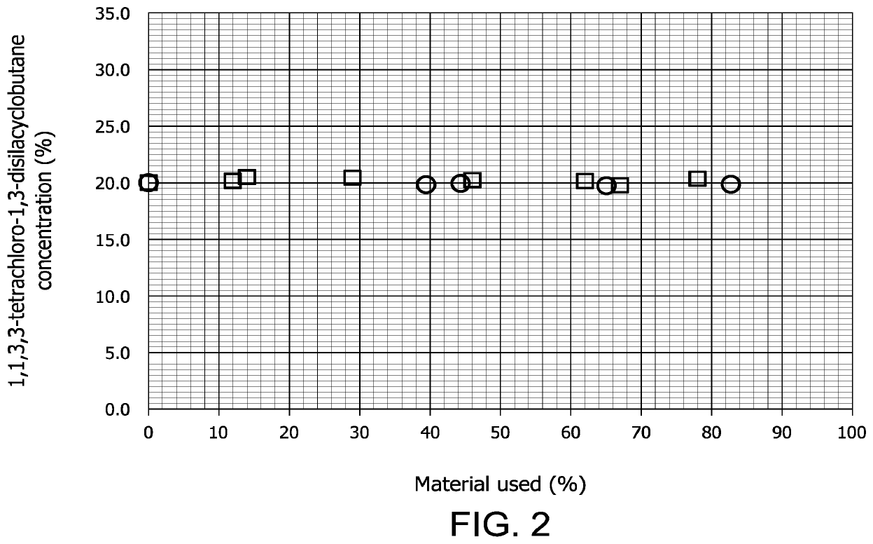

FIG. 2 shows the normalized concentration of the common constituent metals of stainless-steel such as Fe, Cr, Ni and Mn in a 20 wt. % solution of 1,1,3,3-tetrachloro-1,3-disilacyclobutane in mesitylene aged for an equivalent of 2 years at room temperature in stainless-steel containers. The fact that these common stainless-steel metals do not increase systematically over time provides strong support that the said formulated product consisting of a low water mesitylene component is compatible with the stainless-steel container.

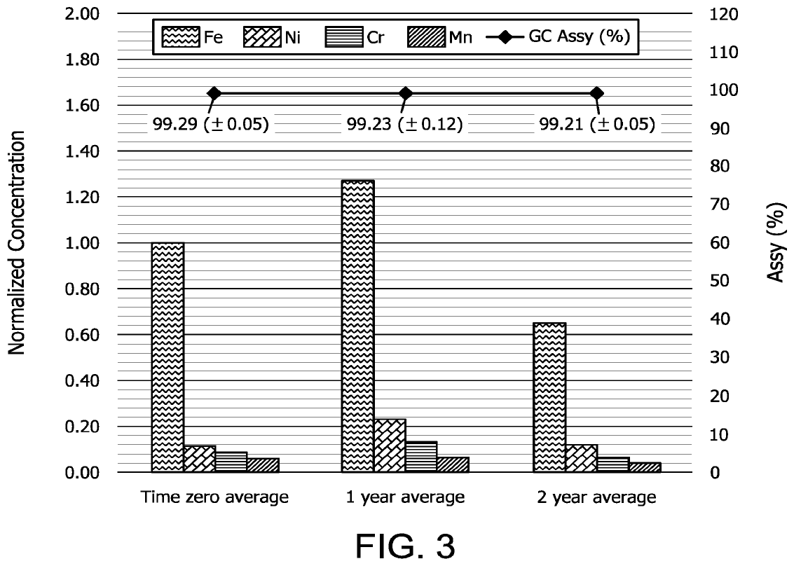

FIG. 3 depicts the normalized concentration of the chlorosilane component, 1,1,3,3-tetrachloro-1,3-disilacyclobutane, as a function of the volume percent remaining in the container as it was depleted during a vapor draw delivery process.

Concentration consistency was performed by depositing silicon containing films using 20% wt. solution of 1,1,3,3-tetrachloro-1,3-disilacyclobutane in mesitylene and ammonia in thermal ALD mode. The container consisted of 200 g of material in 500 ml stainless steel container. The container was heated to 80° C. and chemical was delivered using vapor draw. Film depositions were performed in a lab scale atomic layer deposition (ALD) reactor using a silicon precursor and ammonia as nitrogen source ammonia. The ALD steps and process conditions are provided in the following Table 3:

TABLE 3
ALD Cycle Steps and Process Conditions

| Steps | Descriptions | Time | | Notes |
|---|---|---|---|---|
| 1 | Insert Si substrates | | | |
| | into a reactor | | | |
| 2 | Heat substrates to | ~1-2 | hours | T = 300° C. |
| | desired temperature | | | |
| 3 | Close throttle valve | 2 | seconds (s) | Throttle valve is |
| | | | | closed to increase |
| | | | | residence time |
| 4 | Deliver silicon | 2 | s | Vapor draw; |
| | precursor dose | | | precursor |
| | | | | exposure was 14 |
| | | | | torr · s |
| 5 | Deliver silicon | 2 | s | Vapor draw |
| | precursor dose | | | |
| 6 | Deliver silicon | 2 | s | Vapor draw |
| | precursor dose | | | |
| 7 | Open throttle valve | 2 | s | |
| 8 | Flow N₂ to | 6 | s | N₂ flow is 5 lpm |
| | purge the reactor | | | |
| 9 | Evacuate the reactor | 6 | s | Base pressure |
| | to base pressure | | | is <1 mTorr |
| 10 | Flow NH₃ | 25 | s | Pressure is set to |
| | | | | 5 Torr; NH₃ flow is |
| | | | | 100 sccm |
| 9 | Flow N₂ to | 6 | s | N₂ flow is 5 lpm |
| | purge the reactor | | | |
| 10 | Evacuate the reactor | 6 | s | Base pressure |
| | to base pressure | | | is <1 mTorr |
| 11 | Remove Si sample | | | |
| | from the reactor | | | |

During the deposition, steps 3 to 10 are repeated for a number of cycles to get a desired thickness of the as-deposited carbon doped silicon nitride

A gas chromatography assay was taken from time to time in between runs in order to check solution concentration.

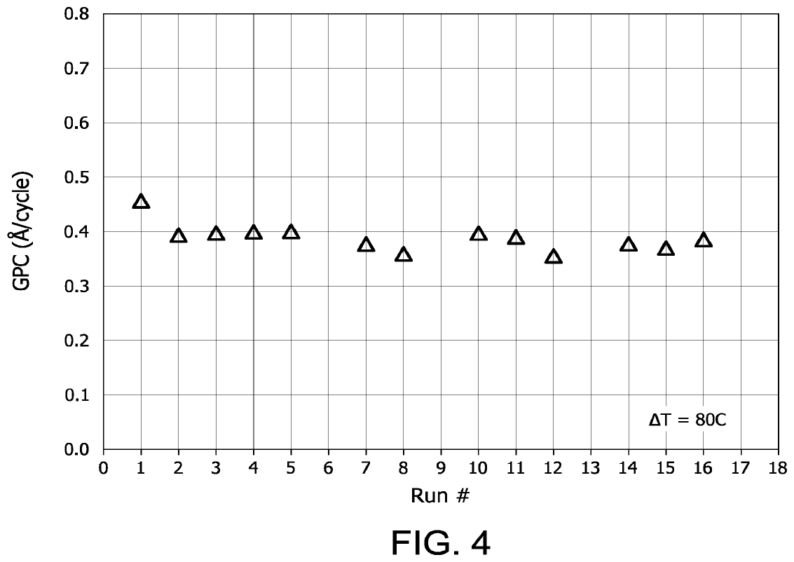

As depicted in FIG. 4, film growth was consistent with GPC of 0.39 Å/cycle±0.03 Å/cycle. A GC assay was taken from the container in between depositions. Tables 4 and 5 represent assays taken at intervals during the deposition with the solution container being heated at temperatures of 80 and 70° C., respectively. As shown in the tables, the precursor concentration is consistent throughout the deposition in either case.

TABLE 4
Solution concentration of the container heated and kept at 80°
C. Assay was taken in between runs. Starting weight was 200 g.

| | Si precursor concentration |
|---|---|
| Material used (%) | (% wt) |
| 0% | 20.00% |
| 39% | 19.85% |
| 44% | 19.95% |
| 65% | 19.76% |
| 83% | 19.86% |

TABLE 5
Solution concentration of the container heated and kept at 70°
C. An assay was taken in between runs. The starting weight was 200 g.

| | Si precursor concentration |
|---|---|
| Material used (%) | (% wt) |
| 0% | 20.00% |
| 12% | 20.15% |
| 14% | 20.52% |
| 29% | 20.44% |
| 46% | 20.21% |
| 62% | 20.12% |
| 67% | 19.81% |
| 78% | 20.35% |

While the invention has been described with reference to certain embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention is not limited to the particular embodiment disclosed as the best mode contemplated for carrying out this invention, but that the invention will include all embodiments falling within the scope of the appended claims.

We claim:

1. A composition for depositing silicon-containing films, the composition comprising:
(a) 1,1,3,3-tetrachloro-1,3-disilacyclobutane; and
(b) mesitylene.

2. The composition of claim 1 comprising less than 5 ppm of at least one metal ion selected from the group consisting of Al³⁺, Fe²⁺, Fe³⁺, Ni²⁺, and Cr³⁺.

3. A method for forming a carbon doped silicon oxide film via a thermal ALD process, the method comprising:
a) placing one or more substrates, each comprising a surface that includes a surface feature, into a reactor;
b) heating the reactor to one or more temperatures ranging from ambient temperature to about 550° C. and optionally maintaining the reactor at a pressure of 100 torr or less;
c) introducing a composition comprising 1,1,3,3-tetrachloro-1,3-disilacyclobutane and mesitylene into the reactor to form a film on the surface;
d) purging the reactor using an inert gas;
e) introducing a nitrogen source into the reactor to react with the film to form a carbon doped silicon nitride film;
f) purging the reactor using an inert gas to remove reaction by-product;
g) repeating steps c to f to provide a desired thickness of the carbon doped silicon nitride film;
h) treating the resulting carbon doped silicon nitride film with an oxygen source at one or more temperatures ranging from about ambient temperature to about 1000° C. to convert the carbon doped silicon nitride film into a carbon doped silicon oxide film; and
i) exposing the carbon doped silicon oxide film to a plasma comprising hydrogen.

4. A film formed according to the method of claim 3 having a k of less than about 4, and a carbon content of at least about 10 at. %.

5. A film formed according to the method of claim 3 having an etch rate in 1:99 dilute HF of at most 0.5 times that of thermal silicon oxide.

6. The film according to claim 5, wherein the etch rate is of at most 0.1 that of thermal silicon oxide.

7. The film according to claim 5, wherein the etch rate is of at most 0.05 times that of thermal silicon oxide.

8. The film according to claim 5, wherein the etch rate is of at most 0.01 times that of thermal silicon oxide.

9. A film formed according to the method of claim 3 having a damage layer of 50 Å or less after exposing the film to an oxygen ashing process.

10. The film according to claim 9, wherein the damage layer is of 20 Å or less after exposing the film to an oxygen ashing process.

11. The film according to claim 9, wherein the damage layer is of 10 Å or less after exposing the film to an oxygen ashing process.

12. The film according to claim 9, wherein the damage layer is of 5 Å or less after exposing the film to an oxygen ashing process.

13. A stainless-steel container housing the composition of claim 1.

14. A method for forming a carbon doped silicon oxide film having carbon content ranging from 15 at % to 30 at. % via a thermal ALD process, the method comprising the method comprising:
a. placing one or more substrates comprising a surface feature into a reactor;
b. heating the reactor to one or more temperatures ranging from ambient temperature to about 150° C. and optionally maintaining the reactor at a pressure of 100 torr or less;
c. introducing a composition comprising 1,1,3,3-tetrachloro-1,3-disilacyclobutane, mesitylene, and a catalyst into the reactor;
d. purging the reactor with an inert gas;
e. providing vapors of water into the reactor to react with 1,1,3,3-tetrachloro-1,3-disilacyclobutane in the presence of the catalyst to form a carbon doped silicon oxide film; and
f. purging the reactor with inert gas to remove any reaction by-products, wherein steps c to f are repeated to provide a desired thickness of the carbon doped silicon oxide film.

15. The method of claim 14 further comprising treating the carbon doped silicon oxide film with a thermal anneal at temperatures of from 300 to 700° C.

16. The method of claim 14 further comprising treating the carbon doped silicon oxide film with a hydrogen plasma comprising hydrogen.

17. The method of claim 3 wherein the composition is introduced into the reactor via vapor draw or bubbling.

18. The method of claim 14 wherein the composition is introduced into the reactor via vapor draw or bubbling.

19. A method for depositing a carbon-doped silicon oxide film having carbon content ranging from 5 at. % to 20 at. % using a thermal ALD process and a plasma comprising hydrogen, the method comprising the steps of:
a. placing one or more substrates comprising a surface into a reactor;
b. heating to reactor to one or more temperatures ranging from ambient temperature to about 550° C. and optionally maintaining the reactor at a pressure of 100 torr or less;
c. introducing a composition comprising 1,1,3,3-tetrachloro-1,3-disilacyclobutane and a solvent selected from the group consisting of mesitylene, 2-methyl-nonane, 1,2,4,5-tetramethylpiperazine, ethoxy-benzene, and 1-ethyl-4-methyl-benzene into the reactor to form a film on the surface;
d. purging the reactor with an inert gas to remove any unreacted composition;
e. introducing a nitrogen source into the reactor to react with the film to form a carbon-doped silicon nitride film;
f. purging the reactor with inert gas to remove any reaction by-products;
g. repeating steps b to e to provide a desired thickness of the carbon-doped silicon nitride film;
h. treating the carbon doped silicon nitride film with an oxygen source at one or more temperatures ranging from about ambient temperature to 1000° C. to convert the carbon doped silicon nitride film into a carbon doped silicon oxide film either in situ or in another chamber; and
i. exposing the carbon doped silicon oxide film to a plasma comprising hydrogen; and
j. optionally treating the carbon doped silicon oxide film with either a spike anneal at temperatures from 400 to 1000° C. or a UV light source.

20. A composition for depositing silicon-containing films, the composition comprising:
(a) 1,1,3,3-tetrachloro-1,3-disilacyclobutane; and
(b) a solvent selected from the group consisting of mesitylene, 2-methyl-nonane, 1,2,4,5-tetramethylpiperazine, ethoxy-benzene, and 1-ethyl-4-methyl-benzene.
